(19) United States
(12) Patent Application Publication
(10) Pub. No.: US 2007/0274033 A1
(43) Pub. Date: Nov. 29, 2007

(54) Drawer-type memory card adapter

(76) Inventor: Chin-hwa Hwang, Taipei City (TW)

Correspondence Address: BACON & THOMAS, PLLC, 625 SLATERS LANE, FOURTH FLOOR, ALEXANDRIA, VA, 22314, US

(21) Appl. No.: 11/441,150

(22) Filed: May 26, 2006

(51) Int. Cl. G06F 1/16; H05K 5/00

(52) U.S. Cl. 361/685; 361/730

(57) ABSTRACT

A drawer-type memory card adapter especially to integrate memory cards of different sizes and specifications in connecting, the adapter comprises a housing, an electric circuit board, at least a pin rank and a drawer, a memory card placed in the drawer can be electrically connected with the drawer-type memory card adapter to get the object of connecting. In other words, the present invention adopts the drawer-type design that is different from the designs of those conventional insertion type and lifting type adapter structures, it can provide an effect of connecting for multiple cards.

### BACKGROUND OF THE INVENTION

1. Field of the Invention

The present invention relates to a drawer-type memory card adapter, and especially to a technique of memory card connecting through a drawer-type memory card adapter for connecting of a plurality of memory cards of different specifications.

2. Description of the Prior Art

The range of usage of memory cards is very wide, for example in using for storing in electronic products such as digital cameras, mobile phones, computers, PDAs, MP3s etc., by virtue that the kinds of memory cards in the markets presently are quite a lot, and the sizes, specifications of the memory cards such as CF cards, SD cards, Micro SD cards, Mini SD cards, MMC Micro cards etc. of various brands are different, a question of whether memory cards of the same specification, size can be used commonly in various electronic products has arisen.

However, some memory cards that are different apparently by specification or size have a certain degree of compatibility in the modes of reading and in the communication circuits they take, while the difference among them is only resided in the sizes of the memory cards such as SD cards, Micro SD cards, MMC Micro cards etc. or as MS Pro cards and MS Pro Dual cards etc.

Therefore, in order to connect for the memory cards of specifications or sizes, manufacturers study and develop adapters. However, the types of conventional adapters mostly go in this way: each of them has an insertion slot on one side of an adapter to allow inserting of a memory card into the adapter and get an effect of connecting; alternatively, a groove is provided on an upper side of an adapter which is provided thereon with a lifting type cartridge to allow placing therein of a memory card, the memory card is positioned in the groove by means of the cartridge, thus an effect of connecting can be effected.

In the technique of known prior art, during connecting of a memory card, the memory card is directly inserted into an insertion slot or a cartridge, in this way, the exterior part of the memory card is subjected to damage by abrasion; some kinds of memory card are quite light and thin structurally, if actions of drawing out or insertion for connecting are wrong or unduly exerted with forces, memory cards may get damage of quite a degree, or even may have firmness of their internal components affected.

And more, during connecting of memory card, an adapter generally can only afford connecting of a memory card with a predetermined size, more memory cards of different specifications are unable to get connecting. Therefore, in connecting for two kinds or more memory cards of different sizes, two kinds of adapters have to be purchased to meet the requirement of a user for connecting; this not only results inconvenience for the user in operation, but also results a situation that the user must carry with him at least two kinds of adapters.

### SUMMARY OF THE INVENTION

In view of the problems resided in the technique of the prior art, the present invention aims at designing an adapter that is not subjected to damaging a memory card in operation, and can integrate memory cards of different sizes and specifications for connecting.

The drawer-type memory card adapter of the present invention comprises: a housing having a drawer groove and a plurality of windows for electric conducting sheets; an electric circuit board provided in the housing and being provided with the electric conducting sheets in opposition to the windows for the electric conducting sheets, at least a pin rank of which one end is in the drawer groove and the other end is electrically connected with the electric circuit board; and a drawer provided in the drawer groove and being provided at least with a positioning groove to make electrically connecting of a memory card with the pin rank when the memory card is inserted into the positioning groove.

The housing includes an upper lid and a lower lid closed to the upper lid, the upper and the lower lids are made of plastic. Alternatively, the upper lid can be made of metal, but in practicing, an insulation element shall be provided between the upper lid and the electric circuit board.

For the sake of making the process of drawing and pulling the drawer more stable and smooth, the housing can be provided at least on one lateral side of the drawer groove with a slide channel, the drawer can be provided at least on one of its lateral sides correspondingly with a slide block for sliding in the slide channel.

### Effects

At least the following effects can be obtained in practicing the present invention:
1. A memory card is placed in the drawer in advance, then the drawer is pushed into the drawer groove, this can avoid the problem induced in the process of drawing and pulling the memory card as is the case of the technique of the prior art.
2. Beside affording insertion of a memory card of a single size and specification for connecting, the present invention can be provided with more than one kind of positioning grooves of different sizes and specifications for placing therein alternatively more than one kind of memory cards of different sizes and specifications for connecting.
3. The present invention is provided with an electric circuit board for electric connecting of a complex pin rank.

The present invention will be apparent after reading the detailed description of the technical measures of two preferred examples thereof in reference to the accompanying drawings.

### BRIEF DESCRIPTION OF THE DRAWINGS

FIG. 1 is a perspective view of a first embodiment of the present invention;

FIG. 2 is an anatomic perspective view of the first embodiment of the present invention;

FIG. 3 is a schematic rear view of the first embodiment of the present invention;

FIG. 4 is a schematic view showing the first using state of the first embodiment of the present invention;

FIG. 5 is a schematic view showing the second using state of the first embodiment of the present invention;

FIG. 6 is a schematic view showing inserting of a Micro SD card in the first embodiment of the present invention;

FIG. 7 is a schematic view showing inserting of an MMC Micro card in the first embodiment of the present invention;

FIG. 8 is a schematic sectional view showing the first using state of the first embodiment of the present invention;

FIG. 9 is a schematic sectional view showing the second using state of the first embodiment of the present invention;

FIG. 10 is an anatomic perspective view of the second embodiment of the present invention.

### DETAILED DESCRIPTION OF THE PREFERRED EMBODIMENT

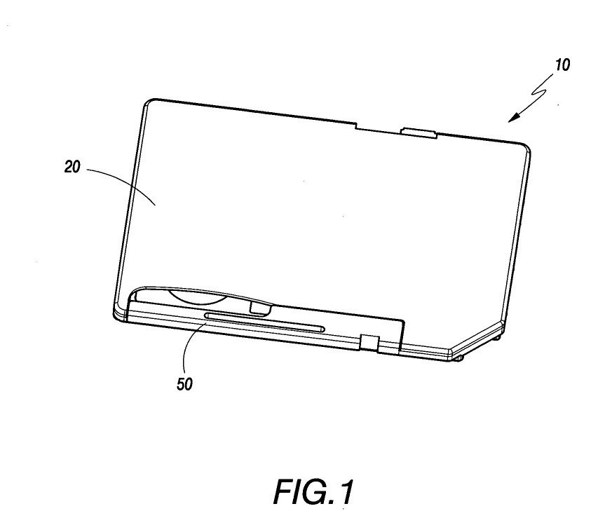

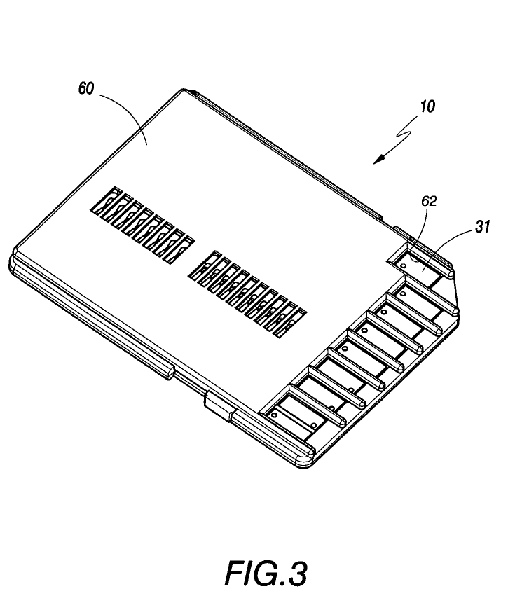

Referring to FIGS. 1-3, the first embodiment of the present invention comprises: an upper lid 20, an electric circuit board 30, a pin rank 40, a drawer 50 and a lower lid 60.

The upper lid 20 and the lower lid 60 are made of plastic, they form a housing after combination, the housing is in a type similar to the shape of an SD card in practicing.

The lower lid 60 has a drawer groove 61 and a plurality of windows 62 for electric conducting sheets 31; the drawer groove 61 is provided at least on one of its two lateral sides with a slide channel 63. The electric circuit board 30, the pin rank 40 and the drawer 50 are received between the upper lid 20 and the lower lid 60.

The electric circuit board 30 is provided with the electric conducting sheets 31 in opposition to the windows 62 for the electric conducting sheets 31, so that the electric conducting sheets 31 are respectively raised and provided on the windows 62.

The pin rank 40 includes a first pin set 41 and a second pin set 42, one end of the pin rank 40 is in the drawer groove 61, and the other end is electrically connected with the electric circuit board 30.

The drawer 50 is provided at least with a positioning groove, in this embodiment, it is provided with a first positioning groove 51 for placing a Micro SD card and a second positioning groove 52 for placing an MMC Micro card; the first positioning groove 51 and the second positioning groove 52 are allocated near one side in the interior of the drawer groove 61, and are provided each with a hole 53, the holes 53 are exactly in opposition to the pin rank 40, and the drawer 50 can be moved by drawing and pulling along the slide channels 63 on the drawer groove 61 to get an effect of opening and closing.

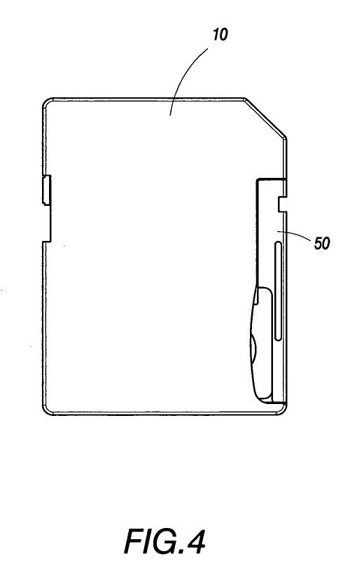

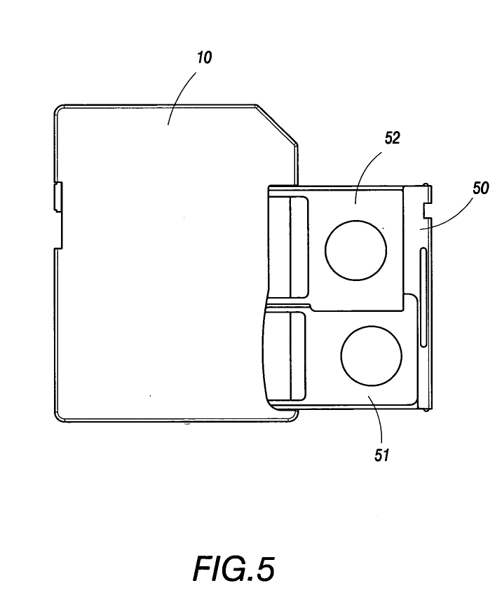

Referring to FIGS. 4 and 5, the drawer 50 is provided in a drawer-type memory card adapter 10, it can be drawn out or pulled into the drawer-type memory card adapter 10; hence when the drawer 50 is drawn out, a Micro SD card or an MMC Micro card can be placed in the first positioning groove 51 or the second positioning groove 52 to be electrically connected with the drawer-type memory card adapter 10.

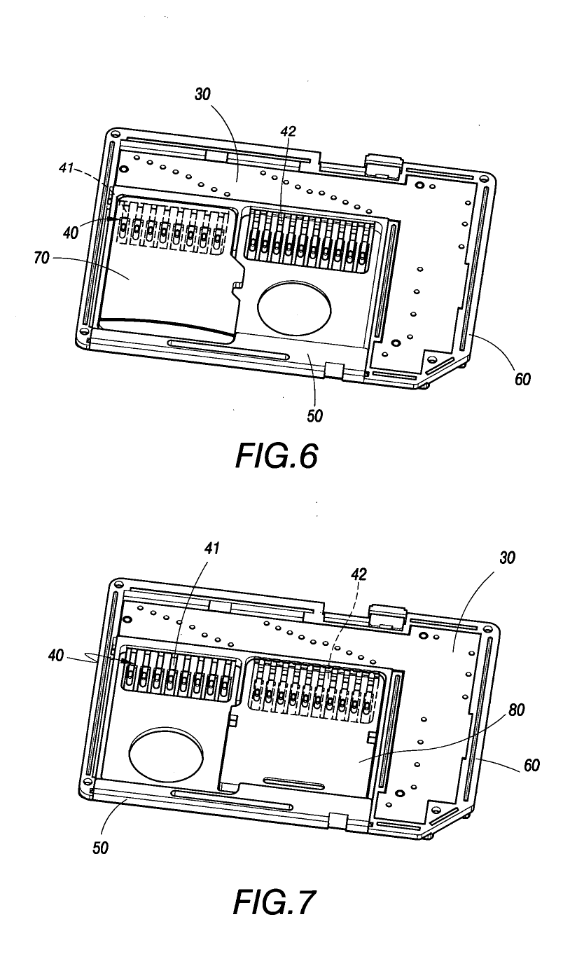

Referring to FIG. 6, when the first positioning groove 51 of the drawer 50 is placed in a Micro SD card 70, the Micro SD card is pushed into the drawer groove 61 of the lower lid 60 to make the first pin set 41 in opposition to the holes 53 connect electrically with the electric circuit board 30 to make connecting for the Micro SD card 70.

Referring to FIG. 7, when the second positioning groove 52 of the drawer 50 is placed in an MMC Micro card 80, the MMC Micro card 80 is pushed into the drawer groove 61 of the lower lid 60 to make the second pin set 42 in opposition to the holes 53 connect electrically with the MMC Micro card 80, thus connecting of the MMC Micro card 80 can be completed through connecting electrically of the electric circuit board 30 with the second pin set 42.

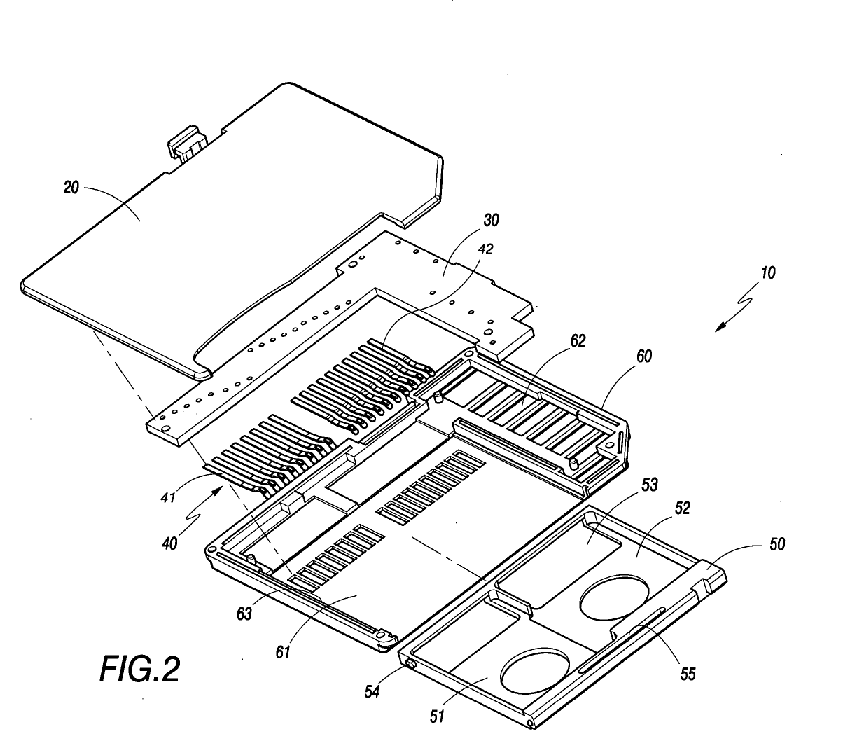

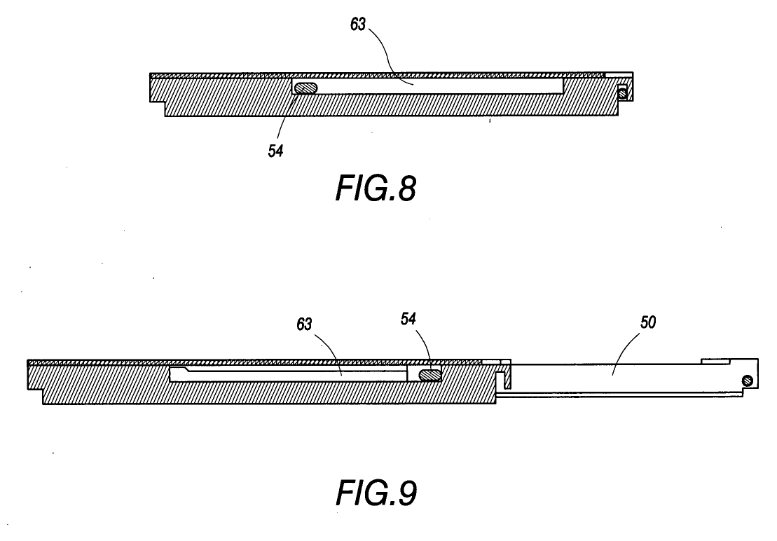

Simultaneously referring to FIGS. 2 and 8, in order to avoid a phenomenon of dropping of the drawer out of the drawer groove 61, the drawer groove 61 at least is provided on its one lateral side with a slide channel 63, and the drawer 50 is provided on at least on one of its two lateral outer sides with a slide block 54 in opposition and corresponding to the slide channel 63.

And for the convenience of drawing and pulling the drawer 50 of by user, the drawer 50-is provided on an outer side of it with a drawing recess 55, so that the user can have an additional force taking area by means of the drawing recess 55, thus the drawer 50 can be drawn out of the drawer groove 61 easily.

Simultaneously referring to FIGS. 8 and 9, by virtue that the drawer 50 is provided on at least on one of its two lateral outer sides with a slide block 54 that are limited to the interior of the slide channel 63; hence in drawing and pulling the drawer 50 inside of the drawer groove 61, the moving space of the drawer 50 will be limited by the lengths of the slide channels 63 to thereby avoid the phenomenon of dropping of the drawer 50 when the user pulls out the drawer 50.

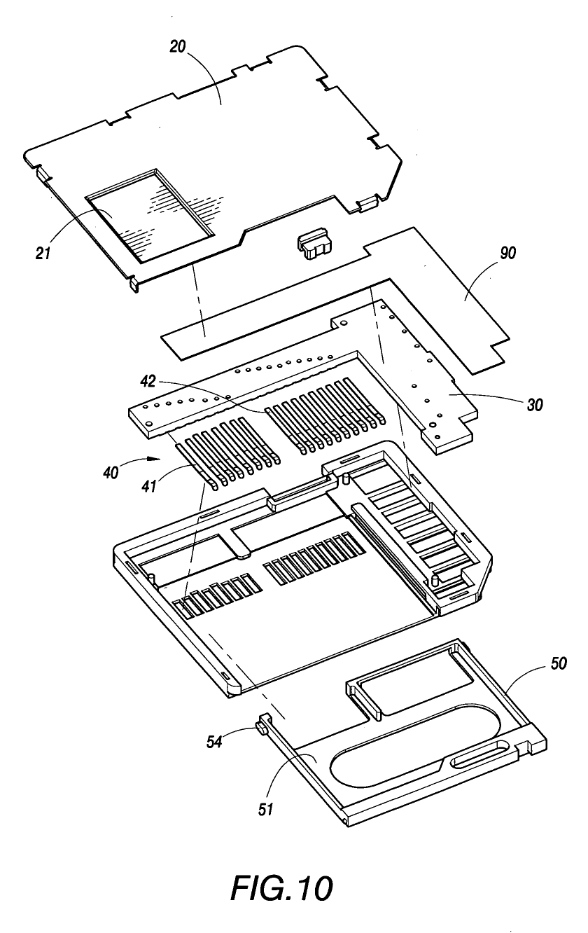

Referring to FIG. 10 which shows the second embodiment of the present invention, the upper lid 20 in the second embodiment mainly is made of metal, in order to avoid interference of the upper lid 20 made of metal with the electric circuit board 30, an insulation element 90 shall be provided between the upper lid 20 and the electric circuit board 30 to obtain an effect of insulating the electric circuit board 30 from the upper lid 20.

Further, the upper lid 20 is provided with a recessed area 21 at a position in corresponding to that of the first positioning groove 51 of the drawer 50, the recessed area 21 is located exactly above the first positioning groove 51, thereby when the Micro SD card is placed in the first positioning groove 51, by abutting of the recessed area 21 on the Micro SD card, positioning of the Micro SD card can be more assured, and the contacting area between the Micro SD card with the pin rank 40 can be increased.

The specification and the drawings for the present invention are only for illustrating the preferred embodiments of the present invention, and not for giving any limitation to the scope of the present invention. It will be apparent to those skilled in this art that various equivalent modifications without departing from the spirit of this invention shall fall within the scope of the appended claims.

1. A drawer-type memory card adapter comprising:
a housing having a drawer groove and a plurality of windows for electric conducting sheets;
an electric circuit board provided in said housing and being provided with said electric conducting sheets in opposition to said windows for said electric conducting sheets;
at least a pin rank of which one end is in said drawer groove and the other end is electrically connected with said electric circuit board; and
a drawer provided in said drawer groove and being provided at least with a positioning groove to make electrically connecting of a memory card with said pin rank when said memory card is inserted into said positioning groove.

2. The drawer-type memory card adapter as in claim 1, wherein
said housing includes an upper lid and a lower lid closed to said upper lid.

3. The drawer-type memory card adapter as in claim 2, wherein
said upper and lower lids are made of plastic.

4. The drawer-type memory card adapter as in claim 2, wherein
said upper lid is made of metal, an insulation element is provided between said upper lid and said electric circuit board.

5. The drawer-type memory card adapter as in claim 1, wherein
said housing is provided at least on one of two lateral sides of said drawer groove with a slide channel, said drawer is provided at least on one of its lateral sides with a slide block for sliding in said slide channel.

6. The drawer-type memory card adapter as in claim 1, wherein
said housing is in a shape of an SD card.

7. The drawer-type memory card adapter as in claim 6, wherein
memory cards for said adapter at least includes Micro SD cards and MMC Micro cards.

8. The drawer-type memory card adapter as in claim 1, wherein
said positioning grooves of said drawer are provided thereon each with a hole to make said memory card directly connect electrically with said pin rank.
